(19) United States
(12) Patent Application Publication
(10) Pub. No.: US 2026/0354089 A1
(43) Pub. Date: Nov. 5, 2026

(54) DETECTION METHOD, SUBSTRATE PROCESSING SYSTEM, AND STORAGE MEDIUM

(71) Applicant: Tokyo Electron Limited, Tokyo (JP)

(72) Inventors: Kazuya KOSHIISHI, Nirasaki City (JP); Eiki ENDO, Nirasaki City (JP)

(21) Appl. No.: 19/712,499

(22) Filed: Jun. 18, 2026

Related U.S. Application Data
(63) Continuation of application No. PCT/JP2024/044730, filed on Dec. 18, 2024.

(30) Foreign Application Priority Data
Dec. 26, 2023 (JP) 2023-219915

(51) Int. Cl. H10P 72/00

(52) U.S. Cl. CPC H10P 72/0466; H10P 72/0454

(57) ABSTRACT

A method of detecting opening/closing of a lid of a substrate container in a substrate processing system, wherein the system includes a loader module delivering substrates to and from the container, wherein the module includes a load port, wherein the load port includes a port door and is configured such that, when the lid is in contact and engaged with the door and the lid is open (first state), the container is in communication with the module, wherein the load port includes an exhauster exhausting the engaged container and a flow rate measurer measuring a flow rate of the exhausted gas, and wherein the method includes: transitioning from the first state to a second state in which the lid is closed; in the second state, releasing the contact and moving the container away from the door; and determining whether the lid is closed normally by measuring the flow rate.

### CROSS-REFERENCE TO RELATED APPLICATION

The application is a Bypass Continuation Application of PCT International Application No. PCT/JP2024/044730, filed on Dec. 18, 2024 and designating the United States, the international application being based upon and claiming the benefit of priority from Japanese Patent Application No. 2023-219915, filed on Dec. 26, 2023, the entire content of which are incorporated herein by reference.

### TECHNICAL FIELD

The present disclosure relates to a detection method, a substrate processing system, and a storage medium.

### BACKGROUND

Patent Document 1 discloses a wafer processing system provided with an optical sensor that detects whether a lid of a FOUP accommodating a plurality of wafers is in a detached state when undocking and unloading the FOUP from a load port.

### PRIOR ART DOCUMENT

### Patent Document

Patent Document 1: Japanese Patent Laid-open Publication No. 2020-061436

### SUMMARY

According to one embodiment of the present disclosure, a detection method for detecting opening and closing of a lid of a substrate container that accommodates a plurality of substrates to be processed in a substrate processing system in multiple stages, wherein the substrate processing system includes a loader module delivering the substrates to and from the substrate container, wherein the loader module includes a load port on which the substrate container is placed, wherein the load port includes a port door and is configured such that, in a first state in which the lid of the substrate container is in contact with and engaged with the port door and the lid of the substrate container is open, an interior of the substrate container is in communication with an interior of the loader module, wherein the load port further includes an exhauster configured to exhaust the interior of the substrate container in a state in which the substrate container is engaged, wherein the exhauster includes a flow rate measurer configured to measure an exhaust flow rate, which is a flow rate of a gas exhausted from the interior of the substrate container, and wherein the detection method includes: (a) transitioning from the first state to a second state in which the lid of the substrate container is closed; (b) in the second state, releasing the contact between the port door and the lid and moving the substrate container in a direction away from the port door; and (c) during execution of (a) and (b), determining whether closing of the lid of the substrate container has been performed normally by measuring the exhaust flow rate while continuously exhausting the interior of the substrate container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically illustrating a configuration of a wafer processing system.

FIG. 2 is a perspective view illustrating an example of configurations of a FOUP and a load port.

FIG. 3 is a diagram illustrating an example of a state in which a FOUP is in contact with a wafer transfer port at a load position.

FIG. 4 is a plan view illustrating an example of a configuration of a bottom portion of a FOUP.

FIG. 5 is a plan view illustrating an example of configurations of a base and a stage in a load port.

FIG. 6 is an explanatory diagram illustrating an example of a configuration of a gas system that supplies a purge gas into a FOUP and exhausts a gas from the FOUP.

FIG. 7 is a cross-sectional view schematically illustrating an example of a state when a lid of a FOUP is opened and closed.

FIG. 8 is a cross-sectional view schematically illustrating an example of a state when the lid of the FOUP is opened and closed.

FIG. 9 is a cross-sectional view schematically illustrating an example of a state when a FOUP is loaded to or unloaded from a load port.

FIG. 10 is a timing chart illustrating an example of a configuration of a detection method and a schematic graph of an exhaust flow rate measured during each process in one state example.

FIG. 11 is a schematic graph of an exhaust flow rate measured during each process in another state example.

### DETAILED DESCRIPTION

Various exemplary embodiments will be described in detail below with reference to the drawings, in which the same or equivalent parts are designated by the same reference numerals. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a semiconductor device manufacturing process, cleanliness of semiconductor wafers (hereinafter referred to as “wafers”) and various wafer processing apparatuses that process the wafers is required. For this purpose, when wafers are transferred from an outside into a wafer processing apparatus, a method for maintaining high cleanliness inside a substrate container called a front-opening unified pod (FOUP) that accommodates a plurality of wafers has been employed.

The above-described substrate container is configured to accommodate a plurality of wafers arranged in parallel to one another in multiple stages and to allow the wafers to be transferred via an opening formed in one surface of the substrate container. An interior of the substrate container is filled with nitrogen gas or the like having high cleanliness, thereby preventing contaminants such as particles from entering the interior of the substrate container.

Such a substrate container includes an openable and closable lid for loading and unloading the wafers. When the substrate container is brought into contact with (docked to) a load port, the lid is opened, and in such a state, the wafers are delivered between the substrate container and a loader module. Further, the lid is closed before the substrate container is released (undocked) from the load port

When the substrate container is undocked, the lid may be insufficiently closed due to deformation of the substrate container or clearance in a latch key for fitting (latching) the lid to a main body of the substrate container in a locked state, or the like. Patent Document 1 discloses providing an optical sensor for detecting whether the lid has been detached during undocking and subsequent unloading of the substrate container.

However, a configuration in which a sensor is provided in a load port increases device cost. Further, when the lid is in an incompletely closed state, the lid does not fall off, and therefore it is difficult to detect such a state with an optical sensor. Accordingly, there is room for improvement in a conventional wafer transfer apparatus.

The present inventors conducted intensive studies in this perspective and conceived of a method of a reference example in which opening and closing of a lid of a substrate container are detected by retracting an opening and closing mechanism (port door) at a load port side after latching the lid, prior to undocking the substrate container. In this method of the reference example, when the port door is retracted while the lid is not normally latched and is incompletely closed, a latch key is caught on the lid and the lid falls off, thereby enabling detection of the incomplete closing of the lid. In contrast to a FOUP 31 of an embodiment described later, in a case where another FOUP that does not have a configuration capable of being supplied with N₂ gas is used, a detection method according to the embodiment described later cannot be performed. Therefore, from the perspective of detecting incomplete closing of a lid of such a FOUP, it is effective to use the method of the reference example, although there are challenges such as maintaining cleanliness when the lid falls into a loader module.

In view of the above-described challenges and the method of the reference example, the technology of the present disclosure detects an open and closed state of a lid of a substrate container. The open and closed state of the lid includes, in addition to detachment of the lid, incomplete closing of the lid.

Hereinafter, a wafer processing system as a substrate processing system and a method of detecting opening and closing of a lid according to the present embodiment will be described with reference to the drawings. In the present specification and drawings, elements having substantially the same functional configurations are denoted by the same reference numerals, and redundant descriptions thereof will be omitted.

### Configuration of Wafer Processing System

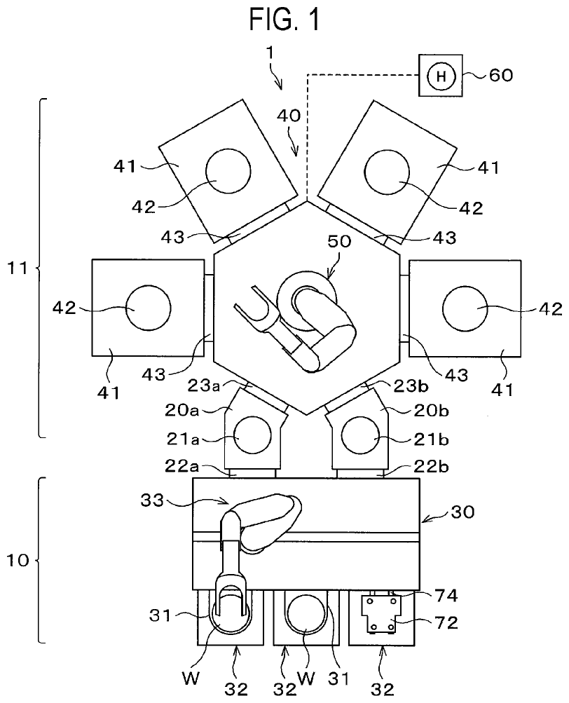

First, a configuration of a wafer processing system as a substrate processing system according to the present embodiment will be described. FIG. 1 is a plan view schematically illustrating a configuration of a wafer processing system 1. In the wafer processing system 1, desired processing such as film formation or etching is performed on a wafer W as a substrate under a reduced pressure atmosphere (vacuum atmosphere). The configuration of the wafer processing system 1 of the present disclosure is not limited thereto and may be arbitrarily selected.

As illustrated in FIG. 1, the wafer processing system 1 has a configuration in which an atmospheric pressure portion 10 and a reduced pressure portion 11 are integrally connected via load-lock modules 20a and 20b. In the atmospheric pressure portion 10, the FOUP 31 to be described later as a substrate container capable of accommodating a plurality of wafers W is transferred under a normal pressure atmosphere (atmospheric atmosphere), and the wafers W are transferred with respect to the load-lock modules 20a and 20b. In the reduced pressure portion 11, desired processing is performed on the wafers W under a reduced pressure atmosphere (vacuum atmosphere), and the wafers W are transferred with respect to the load-lock modules 20a and 20b.

A stage 21a on which a wafer W is placed is provided inside the load-lock module 20a. The load-lock module 20a temporarily holds the wafer W on the stage 21a in order to deliver the wafer W transferred from a loader module 30 (described later) of the atmospheric pressure portion 10 to a transfer module 40 (described later) of the reduced pressure portion 11.

The load-lock module 20a is connected to the loader module 30 (described later) via a gate valve 22a. The load-lock module 20a is connected to the transfer module 40 (described later) via a gate valve 23a. These gate valves 22a and 23a ensure both airtightness and communication among the load-lock module 20a, the loader module 30, and the transfer module 40.

A gas supplier (not shown) for supplying a gas and an exhauster (not shown) for exhausting a gas are connected to the load-lock module 20a, and an interior of the load-lock module 20a is configured to be switchable between the normal pressure atmosphere and the reduced pressure atmosphere by the gas supplier and the exhauster. That is, the load-lock module 20a is configured to enable appropriate delivery of the wafer W between the atmospheric pressure portion 10 under the normal pressure atmosphere and the reduced pressure portion 11 under the reduced pressure atmosphere.

The load-lock module 20b has the same configuration as the load-lock module 20a. That is, the load-lock module 20b includes a stage 21b on which a wafer W is placed, a gate valve 22b on a side of the loader module 30, and a gate valve 23b on a side of the transfer module 40.

The number and arrangement of the load-lock modules 20a and 20b are not limited to the present embodiment and can be arbitrarily set.

The atmospheric pressure portion 10 includes the loader module 30 provided with a wafer transfer device 33, and a load port 32 on which the FOUP 31 capable of storing a plurality of wafers W is placed. The loader module 30 is also referred to as an equipment front end module (EFEM).

The loader module 30 is configured as a housing having an interior of a substantially rectangular shape, and the interior of the housing is maintained at a pressure equal to or higher than an ambient atmosphere outside the wafer processing system 1. On one side surface constituting long sides of the housing of the loader module 30, a plurality of load ports 32, for example, three load ports 32 are arranged side by side. FIG. 1 illustrates a state in which the load ports 32 at a left-hand side and a center of the drawing are loaded with the FOUPs 31 and the FOUP 31 is not loaded on the load port 32 at a right-hand side of the drawing. On the other side surface constituting the long sides of the housing of the loader module 30, the load-lock modules 20a and 20b are arranged side by side. The loader module 30 includes the wafer transfer device 33 movable in a longitudinal direction within the housing. The wafer transfer device 33 is capable of delivering the wafer W between the FOUPs 31 placed on the load ports 32 and the load-lock modules 20a and 20b. Details of configurations of the FOUPs 31 and the load ports 32 will be described later.

The reduced pressure portion 11 includes the transfer module 40 that transfers the wafer W and a processing module 41 serving as a substrate processing apparatus that performs desired processing on the wafer W. An interior of the transfer module 40 and an interior of the processing module 41 are each maintained at the reduced pressure atmosphere. A plurality of processing modules 41, for example, four processing modules 41 are provided with respect to the transfer module 40. The transfer module 40 is also referred to as a vacuum transfer module (VTM).

The transfer module 40 is configured as a housing having an interior of a polygonal shape in a plan view, and in the illustrated example, the housing has a hexagonal shape in a plan view. As described above, the transfer module 40 is connected to the load-lock modules 20a and 20b via the gate valves 23a and 23b, respectively. That is, the load-lock modules 20a and 20b and the four processing modules 41 are disposed at respective side surface portions of the transfer module 40. The transfer module 40 sequentially transfers the wafer W transferred to the load-lock module 20a to the respective processing modules 41 to perform desired processing, and then carries the wafers W out to the atmospheric pressure portion 10 via the load-lock module 20b.

A wafer transfer device 50 for transferring the wafer W among the load-lock modules 20a and 20b, the transfer module 40, and the processing modules 41 is provided inside the transfer module 40.

A stage 42 on which the wafer W is placed is provided inside the processing module 41. The processing module 41 performs desired processing such as film formation or etching on the wafer W placed on the stage 42. A gas supplier (not shown) for supplying a process gas or a purge gas and an exhauster (not shown) for exhausting a gas are connected to the processing module 41.

The processing module 41 is connected to the transfer module 40 via a gate valve 43. The gate valve 43 ensures both airtightness and communication between the transfer module 40 and the processing module 41.

The number and arrangement of the processing modules 41 provided with respect to the transfer module 40 and types of processing performed by the processing modules 41 are not limited to the present embodiment and can be arbitrarily set.

The wafer processing system 1 described above is provided with a controller 60. The controller 60 processes computer-executable instructions to cause the wafer processing system 1 to execute various processes described in the present disclosure. The controller 60 may be configured to control individual components of the wafer processing system 1 so as to execute the various processes described herein. In one embodiment, a part or all of the controller 60 may be included in the wafer processing system 1. The controller 60 may include a processor, a storage, and a communication interface. The controller 60 is implemented by, for example, a computer. The processor may be configured to read a program from the storage and execute the read program to perform various control operations. The program may be stored in the storage in advance or may be acquired via a medium when necessary. The acquired program is stored in the storage and is read from the storage and executed by the processor. The medium may be any non-transitory computer-readable storage medium or a communication line connected to the communication interface. The processor may be a central processing unit (CPU). The storage may be either transitory or non-transitory and may include a random access memory (RAM), a read-only memory (ROM), a hard disk drive (HDD), a solid state drive (SSD), or a combination of two or more of these. The communication interface may communicate with the wafer processing system 1 via a communication line such as a local area network (LAN).

### FOUP and Load Port

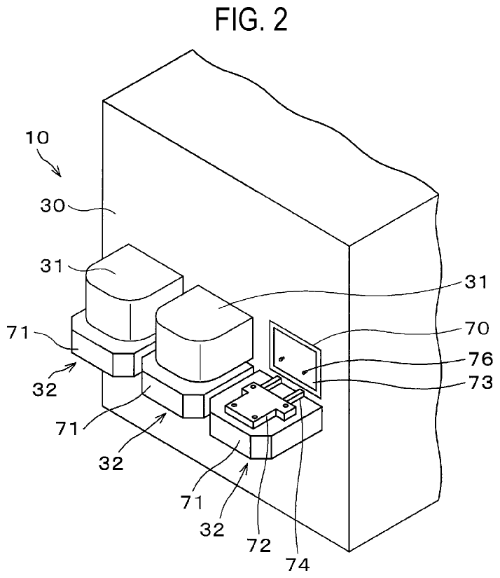

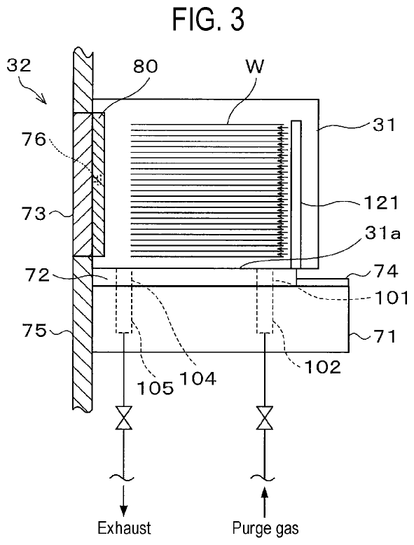

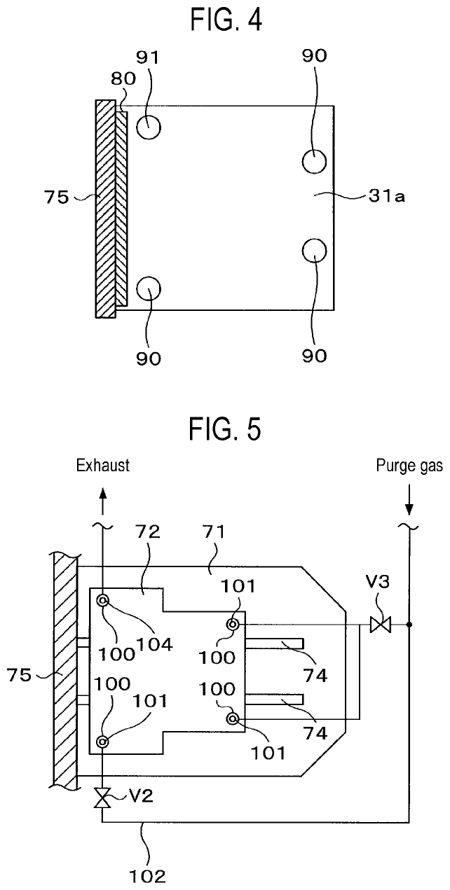

FIG. 2 is a perspective view illustrating an example of configurations of the FOUP 31 and the load port 32. FIG. 3 is a cross-sectional view taken in a direction perpendicular to the longitudinal direction of the loader module, and illustrates an example of a state in which the FOUP 31 is in contact with (docked to) a wafer transfer port 70 at a load position. FIG. 4 is a plan view illustrating an example of a configuration of a bottom portion of the FOUP 31. FIG. 5 is a plan view illustrating an example of configurations of a base 71 and a stage 72 in the load port 32.

As illustrated in FIG. 2, each load port 32 includes the wafer transfer port 70, the base 71, the stage (placement table) 72 on which the FOUP 31 is placed, and a port door 73 that closes the wafer transfer port 70. The stage 72 advances and retracts along a rail 74 extending in a front-rear direction by a stage movement mechanism (not shown). By the advancing and retracting movement of the stage 72, the FOUP 31 moves between an unload position, which is a retracted position, and the load position, which is an advanced position. A state in which the FOUP 31 is placed at the unload position is illustrated. The FOUP 31 is transferred onto the stage 72 located at the unload position in a state in which a grip portion (not shown) thereof is gripped by an appropriate transfer device. Subsequently, the stage 72 is advanced, and at the load position, the FOUP 31 and the loader module 30 are connected, thereby enabling delivery of the wafers W by the wafer transfer device 33. A wall surface of the loader module 30 except for the wafer transfer port 70 is referred to as a partition wall 75. The port door 73 includes a latch key 76 for latching the FOUP 31 and a lid 80, as will be described later.

As illustrated in FIG. 3, the FOUP 31 has a box-like shape with an opening at a front side and includes the lid 80 that seals the opening. In the following description, in a state in which the FOUP 31 is docked to the wafer transfer port 70, the lid 80 is docked to the port door 73. A bottom portion 31a of the FOUP 31 is configured to be supported by the stage 72.

The stage 72 is provided with a desired engagement member (not shown), and the stage 72 and the FOUP 31 can be engaged (clamped) at a desired position by the engagement member. The FOUP 31 is provided with a support mechanism corresponding to a mechanism of the engagement member. That is, a state in which the FOUP 31 is “clamped” to the stage 72 refers to completion of a control for performing engagement by a mechanical action of the engagement member of the stage 72 with respect to the support mechanism of the FOUP 31. Conversely, a state in which the FOUP 31 is “unclamped” from the stage 72 refers to completion of a control for releasing the engagement by a mechanical action of the engagement member of the stage 72 with respect to the support mechanism of the FOUP 31. The stage 72 may include desired positioning pins (not shown) and may be configured to guide the FOUP 31 to an accurate position by using the positioning pins during clamping.

The lid 80 includes a fitting member (not shown) and is configured to be airtightly closable while the lid 80 and the FOUP 31 are in close contact with each other. The lid 80 is provided with a keyhole (not shown) at a position facing the latch key 76 in a state in which the lid 80 is docked to the port door 73. The lid 80 and the FOUP 31 are provided with a desired locking mechanism (not shown), and in a state in which the latch key 76 is fit into the keyhole, the fitting member is moved by an operation of the latch key 76 so that the lid 80 is in a locked (latched) state with respect to the FOUP 31. That is, a state in which the lid 80 is “latched” to the FOUP 31 refers to completion of a control of a series of operations for moving the fitting member to bring the lid 80 into the locked state with respect to the FOUP 31. Conversely, a state in which the lid 80 is “unlatched” refers to completion of a control of a series of operations for moving the fitting member to release the locked state of the lid 80 with respect to the FOUP 31. The port door 73 is configured to be openable and closable by a drive mechanism (not shown). Therefore, the lid 80 can be opened and closed by opening and closing operations of the port door 73 in a state in which the port door 73 and the lid 80 are docked and the latch key 76 is fit into the keyhole.

The wafers W, for example, twenty-five wafers W, to be processed by the wafer processing apparatus are accommodated in the FOUP 31. The wafers W are disposed horizontally and in multiple stages with equal intervals within the FOUP 31.

As illustrated in FIG. 4, three gas supply ports 90 and one gas exhaust port 91 are provided in the bottom portion 31a of the FOUP 31. In the present embodiment, among the gas supply ports 90, two are disposed on a side opposite to the lid 80, and one is disposed on a side of the lid 80. The gas exhaust port 91 is disposed on the side of the lid 80.

As illustrated in FIG. 5, through-holes 100 are provided in the stage 72 at positions corresponding to the gas supply ports 90 and the gas exhaust port 91 provided in the FOUP 31. In the base 71, gas supply connectors 101 are provided at positions corresponding to the gas supply ports 90 of the FOUP 31. A flexible gas supply pipe 102 is connected to the gas supply connectors 101. A gas source (not shown) is connected to an opposite end of the gas supply pipe 102, to supply a dried purge gas, for example, N₂ gas, via the gas supply pipe 102. In the base 71, an exhaust connector 104 is provided at a position corresponding to the gas exhaust port 91 of the FOUP 31. A flexible exhaust pipe 105 is connected to the exhaust connector 104.

The gas supply connectors 101 and the exhaust connector 104 are configured to be raised and lowered by a lifting mechanism (not shown) such as an air cylinder. A ring-shaped sealing member (not shown) is provided at a tip of each of the gas supply connectors 101 and the exhaust connector 104. With this configuration, by raising the gas supply connectors 101, the gas supply connectors 101 communicate with the gas supply ports 90 of the FOUP 31, making it possible to supply the purge gas into the FOUP 31. By raising the exhaust connector 104, the exhaust connector 104 communicates with the gas exhaust port 91 of the FOUP 31, making it possible to exhaust an interior of the FOUP 31.

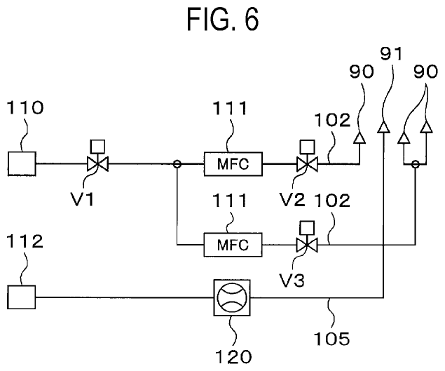

FIG. 6 is an explanatory diagram illustrating an example of a configuration of a gas system configured to supply the purge gas to the FOUP 31 and to exhaust a gas from the FOUP 31 according to the present embodiment. A gas source 110 for supplying, for example, dry nitrogen as the purge gas is connected to the gas supply ports 90 via the gas supply pipe 102. The gas supply pipe 102 is provided with a valve V1 for controlling supply and stop of a gas from the gas source 110. The gas supply pipe 102 branches into two branches at a downstream side of the valve V1. The branches of the gas supply pipe 102 are provided with shutoff valves V2 and V3, respectively. Each of the branches of the gas supply pipes 102 is provided with a mass flow controller (MFC) 111 which controls the supply of the purge gas to a corresponding one of the gas supply ports 90 at a desired flow rate.

An exhaust mechanism 112 is connected to the gas exhaust port 91 via the exhaust pipe 105, so that the gas supplied from each gas supply port 90 can be exhausted. The exhaust pipe 105 is provided with a flow meter 120 serving as a flow rate measurer according to the present embodiment so that a flow rate of an exhaust gas flowing through the exhaust pipe 105 can be measured. A flow rate measured by the flow meter 120 is transmitted to, for example, the controller 60.

Returning to FIG. 3, the two gas supply ports 90 disposed on the side opposite to the lid 80 are provided with distribution pipes 121 extending vertically upward within the FOUP 31. In the distribution pipe 121, for example, slit-shaped openings (not shown) are formed in a surface facing the wafers W at heights corresponding to gaps among the wafers W, so that the gas supplied from the gas supply ports 90 can be uniformly distributed among the wafers W. Accordingly, a gas flow that uniformly flows among the wafers W in a direction from the interior of the FOUP 31 toward the lid 80 can be formed inside the FOUP 31. As a result, even when the lid 80 is open, this gas flow can prevent the atmosphere inside the loader module 30 from entering the interior of the FOUP 31.

Details such as the arrangement of the gas supply ports 90 or the gas exhaust port 91, and the necessity of installing the distribution pipe 121 are not limited to the present embodiment. For example, any arbitrary setting, such as providing two gas supply ports 90 and two gas exhaust ports 91, can be applied.

The number and arrangement of the load ports 32 are also not limited to the present embodiment and can be arbitrarily set. Further, the atmospheric pressure portion 10 may also be provided with a processing module that performs desired processing on the wafer W under the normal pressure atmosphere, for example, a module that performs an alignment process of adjusting an orientation of the wafer W in a horizontal direction.

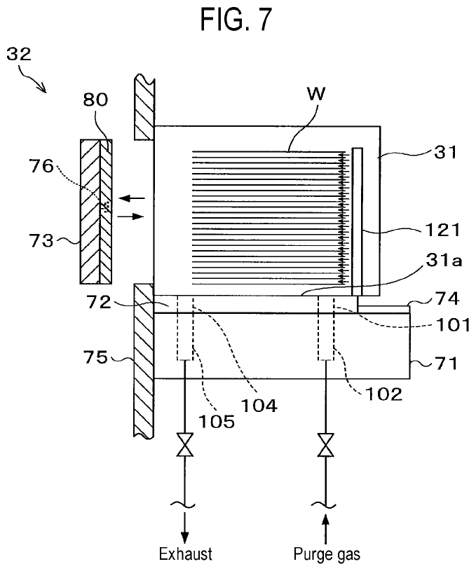

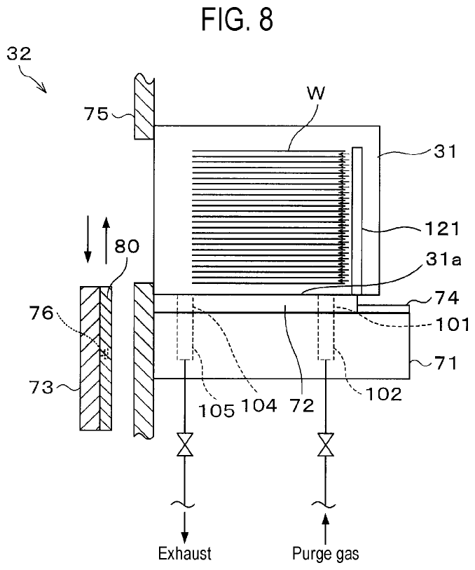

FIGS. 7 and 8 are cross-sectional views schematically illustrating examples of states when the lid of the FOUP 31 having the above configuration is opened and closed. When the lid 80 of the FOUP 31 is opened, as illustrated in FIG. 7, the latch of the lid 80 with respect to the FOUP 31 is first released (unlatched), and subsequently, a composite body in which the port door 73 and the lid 80 are docked moves horizontally by a movement mechanism (not shown). Thereafter, as illustrated in FIG. 8, the composite body in which the port door 73 and the lid 80 are docked moves downward along the partition wall 75. As a result, the wafer transfer device 33 of the loader module 30 becomes capable of accessing the wafers W inside the FOUP 31. When the lid 80 of the FOUP 31 is closed, the composite body in which the port door 73 and the lid 80 are docked moves in a reverse direction of that during the opening.

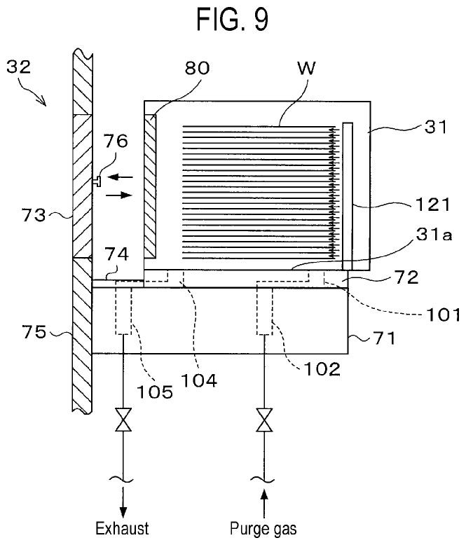

FIG. 9 is a cross-sectional view schematically illustrating an example of a state when the FOUP 31 is loaded to or unloaded from the load port 32. When the FOUP 31 is unloaded, in a state in which the FOUP 31 is docked to the load port 32 and the lid 80 is open as illustrated in FIG. 7, first, the lid 80 is closed and latched. Thereafter, the FOUP 31 is undocked from the wafer transfer port 70, and the stage 72 moves in a direction away from the port door 73, so that the FOUP 31 is moved to the unload position, which is the retracted position. When the FOUP 31 is loaded, the FOUP 31 moves in a reverse direction of the above-described direction. As illustrated in FIG. 9, the flexible gas supply pipe 102 and the flexible exhaust pipe 105 move following the movement of the FOUP 31 while maintaining connection to the gas supply connectors 101 and the exhaust connector 104, respectively.

### Method of Detecting Opening and Closing of Lid of Substrate Container

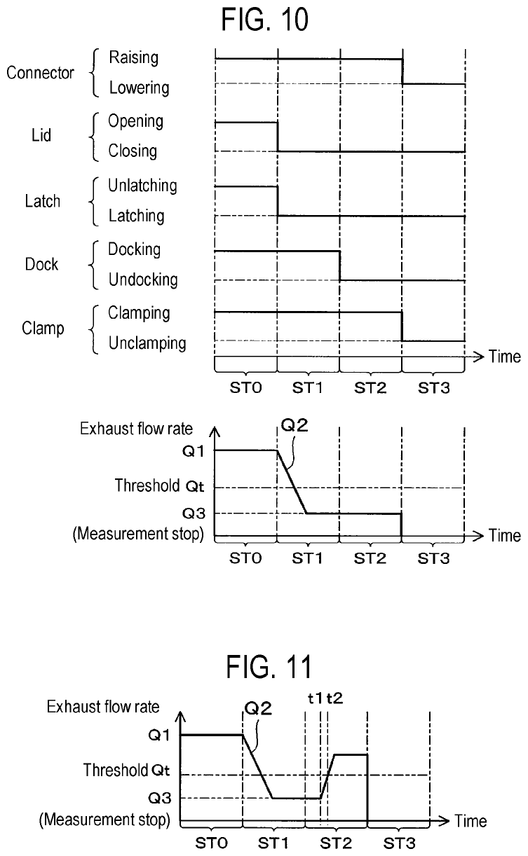

Next, a method of detecting opening and closing of the lid 80 of the FOUP 31 according to the present embodiment will be described. FIG. 10 is a timing chart illustrating an example of a configuration of a detection method according to the present embodiment and a schematic graph of an exhaust flow rate measured during each process. In the timing chart, the horizontal axis represents time and the vertical axis represents a state of each component. In the graph of the exhaust flow rate, the horizontal axis represents time and the vertical axis represents the exhaust flow rate.

In the detection method according to the present embodiment, an open and closed state of the lid 80 is detected during a continuous period from a state in which the FOUP 31 is loaded onto the load port 32 and the lid 80 is open to a state in which the lid 80 is closed and the FOUP 31 is unloaded from the load port.

In an initial state ST0 before a start of step ST1, the FOUP 31 is loaded onto the load port 32 and the lid 80 is open, and the interior of the FOUP 31 is in communication with an interior of the loader module 30. Such a state of the FOUP 31 is referred to as a first state. For example, the state in FIG. 7 or FIG. 8 is the first state. In the first state, the gas supply connectors 101 are in communication with the gas supply pipe 102, and the exhaust connector 104 is in communication with the exhaust pipe 105. In addition, the purge gas is supplied into the FOUP 31 at a desired supply flow rate via the gas supply connectors 101 and the gas supply ports 90, and the gas inside the FOUP 31 is exhausted via the gas exhaust port 91 and the exhaust connector 104. The flow meter 120 provided in the exhaust pipe 105 measures the flow rate of the exhaust gas flowing through the exhaust pipe 105 (hereinafter referred to as an “exhaust flow rate”). An exhaust flow rate measured in the initial state ST0 is a first flow rate Q1.

In step ST1, as illustrated in FIG. 7, the composite body in which the port door 73 and the lid 80 are docked is moved to close the FOUP 31. Thereafter, the above-described locking mechanism by the latch key 76 is operated to latch the lid 80 and the FOUP 31. The exhaust flow rate is continuously measured from before execution of step ST1. A state of the latched FOUP 31 after being closed by the lid 80 is referred to as a second state. In step ST1, an exhaust flow rate measured in the FOUP 31 after entering the second state is a second flow rate Q2. In a state example of FIG. 10 in which closing and latching of the lid 80 are performed normally, the second flow rate Q2 gradually decreases from the first flow rate Q1 as an initial value, and thereafter gradually approaches a third flow rate Q3, which is a stabilized value. Although the second flow rate Q2 illustrated in FIG. 10 follows a linear graph decreasing at a constant slope, the present disclosure is not limited thereto and includes cases in which the second flow rate Q2 follows a non-linear graph due to non-uniform decrease. When the exhaust flow rate gradually approaches a value sufficiently close to the third flow rate Q3, it is defined that “the exhaust flow rate has reached the third flow rate Q3.” The significance of the first to third flow rates Q1 to Q3 will be described later.

In step ST2, the lid 80 is undocked from the port door 73, and the FOUP 31 is moved in a direction away from the wafer transfer port 70 to the unload position. The exhaust flow rate is continuously measured from step ST1. The exhaust flow rate measured in step ST2 is the third flow rate Q3.

In step ST3, measurement of the exhaust flow rate is terminated, communication between the gas supply connectors 101 and the gas supply pipe 102 is disconnected, and communication between the exhaust connector 104 and the exhaust pipe 105 is disconnected. Thereafter, the engagement between the FOUP 31 and the stage 72 is released (unclamped).

Thereafter, the FOUP 31 may be removed from the stage 72 and transferred to another processing apparatus that performs other processing on the wafers W.

Here, the significance of the first to third flow rates Q1 to Q3, which are exhaust flow rates measured during the execution from the initial state ST0 to step ST2, will now be described. In the initial state ST0, the interior of the FOUP 31 is in communication with the interior of the loader module 30. As described above, the interior of the loader module 30 is maintained at a pressure equal to or higher than the ambient atmosphere outside the wafer processing system 1. Therefore, based on such a pressure gradient, a gas flows from the loader module 30 into the FOUP 31, and the flow rate of a gas exhausted from the FOUP 31 becomes the first flow rate Q1 which is relatively large.

In step ST1, communication between the loader module 30 and the FOUP 31 is disconnected as the lid 80 is closed. Accordingly, inflow of the gas from the loader module 30 into the FOUP 31 stops, and a gas remaining inside the FOUP 31 immediately after the closing of the lid 80 is sequentially exhausted. As a result, an amount of the gas remaining inside the FOUP 31 decreases, and the second flow rate Q2 as the exhaust flow rate decreases accordingly. Thereafter, as a pressure of the gas inside the FOUP 31 approaches equilibrium with a suction pressure for exhaust in the exhaust mechanism 112, the exhaust flow rate reaches the third flow rate Q3, which is a stabilized value.

In the state example shown in FIG. 10, during the execution of steps ST1 to ST3, once the exhaust flow rate falls below a threshold Qt of a certain flow rate, the exhaust flow rate does not exceed the threshold Qt again until completion of step ST3. In such a case, it is determined that the FOUP 31 has been normally closed by the lid 80.

On the other hand, in another state example, during the execution of steps ST1 to ST3, the exhaust flow rate may once fall below the threshold Qt of the certain flow rate and then exceed the threshold Qt again. FIG. 11 is a schematic graph of the exhaust flow rate measured during each process in such a state example. In FIG. 11, the horizontal axis represents time and the vertical axis represents the exhaust flow rate.

In the state example shown in FIG. 11, after the exhaust flow rate reaches the third flow rate Q3 in step ST1, the exhaust flow rate increases in step ST2 and exceeds the threshold Qt. The reason for such a change in flow rate is considered as follows. First, in this state example, after the FOUP 31 is closed by the lid 80 in step ST1, the lid 80 and the FOUP 31 are not properly latched due to a clearance or the like in the latch key. Thereafter, in this state, when the lid 80 is undocked from the port door 73 in step ST2 and the FOUP 31 is moved slightly, the latch key 76 is caught by the keyhole or the like in the lid 80, causing the lid 80 to be removed and the FOUP 31 to be open from a closed state. When the FOUP 31 is open in the undocked state, the interior of the FOUP 31 is in communication with the ambient atmosphere outside the wafer processing system 1. A pressure of the ambient atmosphere is lower than an internal pressure of the loader module 30, but is higher than an internal pressure of the FOUP 31 when the exhaust flow rate from the FOUP 31 is the third flow rate Q3. In addition, the pressure of the ambient atmosphere is higher than the internal pressure of the FOUP 31 when the exhaust flow rate from the FOUP 31 is at the threshold Qt. Therefore, when the interior of the FOUP 31 is in communication with the ambient atmosphere, the exhaust flow rate switches to increase and, as a result, exceeds the threshold Qt.

For the reasons described above, when the exhaust flow rate once falls below the threshold Qt of the certain flow rate and then exceeds the threshold Qt again, it is determined that closing of the lid 80 has not been performed normally. When it is determined that closing of the lid 80 has not been performed normally, the controller 60 issues, for example, an alarm.

In one embodiment, detection of closing of the lid 80 is performed without using the threshold Qt for the exhaust flow rate. In this case, as an example, when it is detected in step ST2 that the exhaust flow rate has switched from a decreasing state to an increasing state after the lid 80 is undocked from the port door 73, it is determined that closing of the lid 80 has not been performed normally.

In another viewpoint, when it is measured that, during the execution of steps ST1 to ST3, the exhaust flow rate has increased by a predetermined threshold of an amount of increase, it is determined that closing of the lid 80 has not been performed normally.

The threshold Qt or the threshold of the amount of increase in the exhaust flow rate can be set in advance by experiments or simulations based on the internal pressure of the loader module 30, the pressure of the ambient atmosphere, the suction pressure for exhaust in the exhaust mechanism 112, an internal volume of the FOUP 31, or the like. The values set in this manner may be stored in the controller 60 and read out during the execution of each step.

In the present embodiment described above, the exhaust flow rate is monitored by the flow meter 120 provided in the exhaust pipe 105, but the present disclosure is not limited thereto. For example, the flow meter 120 may be provided anywhere on an exhaust line and may be provided, for example, in the exhaust mechanism 112. When the flow meter 120 has a function of measuring a pressure, the pressure may be monitored.

According to the method of detecting opening and closing of the lid 80 of the FOUP 31 according to the present embodiment as described above, the opening and closing of the lid 80 can be detected by a simple configuration in which the flow meter 120 is provided in the exhaust pipe 105, without separately providing a sensor, such as an optical sensor, for detecting the opening and closing of the lid 80.

Unlike the above-described method in which the port door 73 is retracted after latching the lid 80, opening and closing of the lid 80 is detected after the port door 73 is fit into the partition wall 75 and the lid 80 is undocked. Therefore, even when the lid 80 is detached during the steps, there is no risk of the lid 80 falling into the interior of the loader module 30. Accordingly, when recovering the detached lid 80, it is not necessary to open the loader module 30 to the ambient atmosphere, and thus, cleanliness of the loader module 30 does not deteriorate. Further, since it is not necessary to open the loader module 30 to the ambient atmosphere, the lid 80 and the FOUP 31 for which an abnormality has been detected can be quickly recovered from the ambient atmosphere, thereby suppressing a decrease in productivity of the wafer processing system 1 as a whole.

Further, since an additional step of retracting the port door 73 after latching the lid 80 is not required, the time required for steps from undocking to unclamping can be reduced.

In addition, since opening and closing of the lid 80 can be detected at a desired timing from closing of the FOUP 31 by the lid 80 to unclamping, the opening and closing of the lid 80 can be detected even at a position outside a detection range of a sensor located away from a load position.

It should be noted that the embodiments disclosed herein are exemplary in all aspects and are not restrictive. The above-described embodiments may be omitted, replaced, or modified in various forms without departing from the scope and spirit of the appended claims. For example, constituent elements of the above embodiments can be arbitrarily combined. From this arbitrary combination, the functions and effects associated with each constituent element of the combination are naturally obtained, and other functions and other effects obvious to those skilled in the art can also be obtained from the description of the present specification.

The effects described herein are illustrative or exemplary only and are not restrictive. That is, the technology of the present disclosure can obtain other effects obvious to those skilled in the art from the description herein in addition to or in place of the above effects.

According to the present disclosure, it is possible to detect an open and closed state of a lid of a substrate container.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A detection method of detecting opening and closing of a lid of a substrate container configured to accommodate a plurality of substrates to be processed in a substrate processing system in multiple stages,
wherein the substrate processing system includes a loader module configured to deliver the substrates to and from the substrate container,
wherein the loader module includes a load port on which the substrate container is placed,
wherein the load port includes a port door and is configured such that, in a first state in which the lid of the substrate container is in contact with and engaged with the port door and the lid of the substrate container is open, an interior of the substrate container is in communication with an interior of the loader module,
wherein the load port further includes an exhauster configured to exhaust the interior of the substrate container in a state in which the substrate container is engaged,
wherein the exhauster includes a flow rate measurer configured to measure an exhaust flow rate, which is a flow rate of a gas exhausted from the interior of the substrate container, and
wherein the detection method comprises:
(a) transitioning from the first state to a second state in which the lid of the substrate container is closed;
(b) in the second state, releasing the contact between the port door and the lid and moving the substrate container in a direction away from the port door; and
(c) during execution of (a) and (b), determining whether closing of the lid of the substrate container has been performed normally by measuring the exhaust flow rate while continuously exhausting the interior of the substrate container.

2. The detection method of claim 1, further comprising (d) comparing the exhaust flow rate with a predetermined threshold and determining that closing of the lid of the substrate container has not been performed normally when the exhaust flow rate falls below the threshold once and then exceeds the threshold again.

3. The detection method of claim 1, further comprising (d) when the exhaust flow rate increases, comparing an amount of increase in the exhaust flow rate with a predetermined threshold of the amount of increase and, when the amount of increase in the exhaust flow rate exceeds the threshold of the amount of increase, determining that closing of the lid of the substrate container has not been performed normally.

4. A substrate processing system, comprising:
a substrate container configured to accommodate a plurality of substrates in multiple stages;
a loader module configured to deliver the substrates to and from the substrate container, and
a controller,
wherein the substrate container includes a lid configured to airtightly close an interior of the substrate container,
wherein the loader module includes a load port on which the substrate container is placed,
wherein the load port includes a port door and is configured such that, in a first state in which the lid of the substrate container is in contact with and engaged with the port door and the lid of the substrate container is open, the interior of the substrate container is in communication with an interior of the loader module,
wherein the load port further includes an exhauster configured to exhaust the interior of the substrate container in a state in which the substrate container is engaged,
wherein the exhauster includes a flow rate measurer configured to measure an exhaust flow rate, which is a flow rate of a gas exhausted from the interior of the substrate container, and
wherein the controller is configured to perform a control including:
(a) transitioning from the first state to a second state in which the lid of the substrate container is closed;
(b) in the second state, releasing the contact between the port door and the lid and moving the substrate container in a direction away from the port door; and
(c) during execution of (a) and (b), determining whether closing of the lid of the substrate container has been performed normally by measuring the exhaust flow rate while continuously exhausting the interior of the substrate container.

5. The substrate processing system of claim 4, wherein the controller is further configured to perform the control further including (d) comparing the exhaust flow rate with a predetermined threshold and determining that closing of the lid of the substrate container has not been performed normally when the exhaust flow rate falls below the threshold once and then exceeds the threshold again.

6. The substrate processing system of claim 4, wherein the controller is further configured to perform the control further including (d) when the exhaust flow rate increases, comparing an amount of increase in the exhaust flow rate with a predetermined threshold of the amount of increase and, when the amount of increase in the exhaust flow rate exceeds the threshold of the amount of increase, determining that closing of the lid of the substrate container has not been performed normally.

7. A non-transitory computer-readable storage medium storing a control program for causing a computer to control a substrate processing system so as to detect opening and closing of a lid of a substrate container configured to accommodate a plurality of substrates to be processed in the substrate processing system in multiple stages,
wherein the substrate processing system includes a loader module configured to deliver the substrates to and from the substrate container,
wherein the loader module includes a load port on which the substrate container is placed,
wherein the load port includes a port door and is configured such that, in a first state in which the lid of the substrate container is in contact with and engaged with the port door and the lid of the substrate container is open, an interior of the substrate container is in communication with an interior of the loader module,
wherein the load port further includes an exhauster configured to exhaust the interior of the substrate container in a state in which the substrate container is engaged,
wherein the exhauster includes a flow rate measurer configured to measure an exhaust flow rate, which is a flow rate of a gas exhausted from the interior of the substrate container, and
wherein the control program causes the computer to control the substrate processing system so as to perform a control including:
(a) transitioning from the first state to a second state in which the lid of the substrate container is closed;
(b) in the second state, releasing the contact between the port door and the lid and moving the substrate container in a direction away from the port door; and
(c) during execution of (a) and (b), determining whether closing of the lid of the substrate container has been performed normally by measuring the exhaust flow rate while continuously exhausting the interior of the substrate container.

8. The non-transitory computer-readable storage medium of claim 7, wherein the control program causes the computer to control the substrate processing system so as to perform the control further including (d) comparing the exhaust flow rate with a predetermined threshold and determining that closing of the lid of the substrate container has not been performed normally when the exhaust flow rate falls below the threshold once and then exceeds the threshold again.

9. The non-transitory computer-readable storage medium of claim 7, wherein the control program causes the computer to control the substrate processing system so as to perform the control further including (d) when the exhaust flow rate increases, comparing an amount of increase in the exhaust flow rate with a predetermined threshold of the amount of increase and, when the amount of increase in the exhaust flow rate exceeds the threshold of the amount of increase, determining that closing of the lid of the substrate container has not been performed normally.
